(19) United States
(12) Patent Application Publication
(10) Pub. No.: US 2017/0063366 A1
(43) Pub. Date: Mar. 2, 2017

(54) SEMICONDUCTOR APPARATUS

(71) Applicant: SK hynix Inc., Icheon-si Gyeonggi-do (KR)

(72) Inventors: Young Ran KIM, Icheon-si Gyeonggi-do (KR); Seung Han OAK, Icheon-si Gyeonggi-do (KR)

(21) Appl. No.: 15/048,174

(22) Filed: Feb. 19, 2016

(30) Foreign Application Priority Data
Aug. 31, 2015 (KR) 10-2015-0122979

(51) Int. Cl. H03K 17/22

(52) U.S. Cl. CPC H03K 17/223

(57) ABSTRACT

A semiconductor apparatus suitable for operating by being applied with a plurality of external voltages from an exterior includes an initialization block configured to enable an initialization signal until all of the plurality of external voltages are higher than preset voltage levels after the plurality of external voltages are initially applied to the semiconductor apparatus; and an internal circuit configured to perform an initialization operation in response to the initialization signal.S

### CROSS-REFERENCES TO RELATED APPLICATION

The present application claims priority under 35 U.S.C. §119(a) to Korean application number 10-2015-0122979, filed on Aug. 31, 2015, in the Korean Intellectual Property Office, which is incorporated herein by reference in its entirety.

### BACKGROUND

1. Technical Field

Various embodiments generally relate to a semiconductor integrated circuit, and, more particularly, to a semiconductor apparatus.

2. Related Art

A semiconductor apparatus operates by being applied with an external voltage from an exterior and generating a voltage of a level needed therein.

While a general semiconductor apparatus operates by being applied with one external voltage from an exterior, a semiconductor apparatus may operate by being applied with a plurality of external voltages in order to perform various internal operations, reduce power consumption of the semiconductor apparatus or stably perform operations.

In the case where a semiconductor apparatus operates by being applied with a plurality of external voltages, since application times of the external voltages are different from one another, an initialization operation error may occur in the semiconductor apparatus or power consumption may increase.

### SUMMARY

In an embodiment, a semiconductor apparatus suitable for operating by being applied with a plurality of external voltages from an exterior may include: an initialization block configured to enable an initialization signal until all of the plurality of external voltages are higher than preset voltage levels after the plurality of external voltages are initially applied to the semiconductor apparatus; and an internal circuit configured to perform an initialization operation in response to the initialization signal.

In an embodiment, a semiconductor apparatus may include: an internal circuit; and an internal control circuit configured to control the internal circuit for an initialization period from a time when one voltage of a first external voltage and a second external voltage is initially applied to the semiconductor apparatus to a time when both the first and second external voltages reach preset voltage levels, and for a normal period after the initialization period.

In an embodiment, a semiconductor apparatus may include: an initialization block configured to generate an initialization signal in response to a first power-up signal and a second power-up signal; a signal combination block configured to generate a combination signal in response to the initialization signal and a control signal; a control block configured to generate the control signal; and an internal circuit configured to operate in response to the combination signal.

### BRIEF DESCRIPTION OF THE DRAWINGS

FIG. 1 is a configuration diagram illustrating a representation of an example of a semiconductor apparatus in accordance with an embodiment.

FIG. 2 is a configuration diagram illustrating a representation of an example of the initialization block shown in FIG. 1.

FIG. 3 is a configuration diagram illustrating a representation of an example of the initialization block shown in FIG. 1.

FIG. 4 is a configuration diagram illustrating a is representation of an example of the signal combination block shown in FIG. 1.

FIG. 5 is a configuration diagram illustrating a representation of an example of the internal circuit shown in FIG. 1.

FIG. 6 illustrates a block diagram of a system employing a semiconductor apparatus in an embodiment of the invention.

### DETAILED DESCRIPTION

Hereinafter, a semiconductor apparatus will be described below with reference to the accompanying drawings through various examples of embodiments.

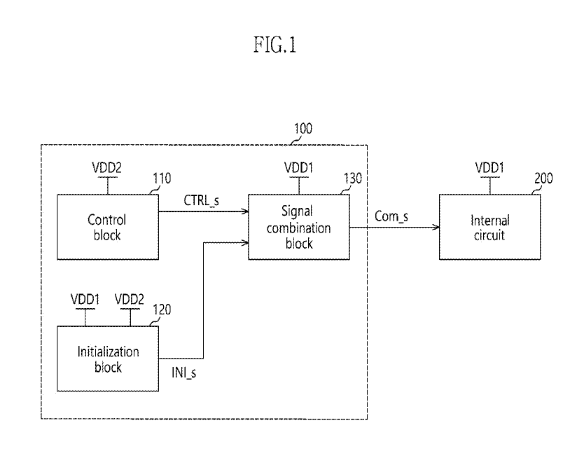

As shown in FIG. 1, a semiconductor apparatus in accordance with an embodiment may include an internal control circuit 100 and an internal circuit 200

The internal control circuit 100 controls the internal circuit 200 for an initialization period from a time when one voltage of a first external voltage VDD1 and a second external voltage VDD2 is initially applied to the semiconductor apparatus to a time when both the first and second external voltages VDD1 and VDD2 reach preset voltage levels, and for a normal period after the initialization period. For example, the internal control circuit 100 generates a combination signal Com_s for an initialization operation of the internal circuit 200 for the initialization period, and generates the combination signal Com_s for a normal operation of the internal circuit 200 for the normal period. In detail, the internal control circuit 100 fixes the combination signal Com_s to a specified level for the initialization period, and transitions the combination signal Com_s according to a situation for the normal period. The first external voltage VDD1 is a voltage which is applied to the semiconductor apparatus earlier than the second external voltage VDD2, and a target level of the first external voltage VDD1 is higher than a target level of the second external voltage VDD2.

The internal control circuit 100 may include a control block 110, an initialization block 120, and a signal combination block 130.

The control block 110 generates a control signal CTRL_s for controlling the internal circuit 200 during the normal period. The control block 110 may be applied with the second external voltage VDD2 as a source voltage.

The initialization block 120 generates an initialization signal INI_s for the initialization period, in response to the first and second external voltages VDD1 and VDD2. For example, the initialization block 120 enables the initialization signal INI_s from a time when one voltage of the first external voltage VDD1 and the second external voltage VDD2 is initially applied to the semiconductor apparatus to a time when both the first and second external voltages VDD1 and VDD2 reach the preset voltage levels, and disables the initialization signal INI_s after the time when both the first and second external voltages VDD1 and VDD2 reach the preset voltage levels.

The signal combination block 130 generates the combination signal Com_s in response to the initialization signal INI_s and the control signal CTRL_s. For example, the signal combination block 130 fixes the combination signal Com_s to the specified level regardless of the control signal CTRL_s, when the initialization signal INI_s is enabled. The signal combination block 130 generates the combination signal Com_s in response to the control signal CTRL_s, when the initialization signal INI_s is disabled. The signal combination block 130 may be applied with the first external voltage VDD1 as a source voltage.

The internal circuit 200 performs the initialization operation and the normal operation in response to the combination signal Com_s. For example, when assuming that the internal circuit 200 in accordance with the embodiment is a driver, the internal circuit 200 performs the initialization operation of fixing an output signal to a specified level when the combination signal Com_s is fixed to the specified level. If the combination signal Com_s is not fixed to the specified level, the internal circuit 200 drives the combination signal Com_s, and outputs the driven combination signal Com_s as the output signal. The internal circuit 200 may be applied with the first external voltage VDD1 as a source voltage.

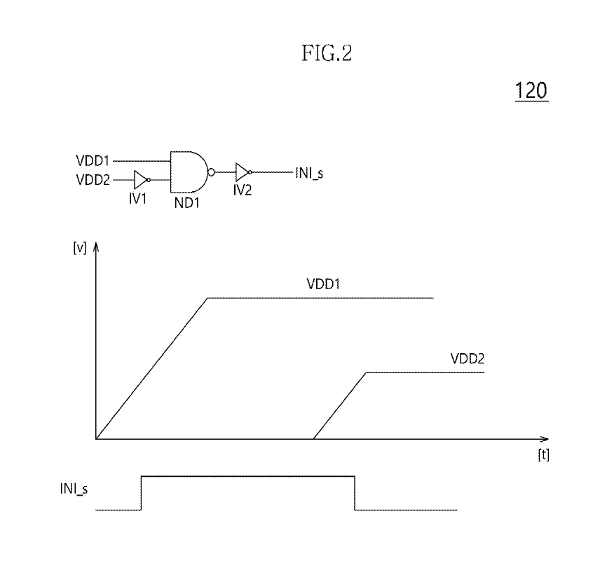

As shown in FIG. 2, the initialization block 120 in accordance with the embodiment may include first and second inverters IV1 and IV2 and a NAND gate ND1. The first inverter IV1 is inputted with the second external voltage VDD2. The NAND gate ND1 is inputted with the first external voltage VDD1 and the output signal of the first inverter IV1. The second inverter IV2 is inputted with the output signal of the NAND gate ND1 and outputs the initialization signal INI_s.

The operation of the initialization block 120 in accordance with the embodiment, configured as mentioned above, will be described below.

The initialization block 120 enables the initialization signal INI_s for a period in which the voltage level of the first external voltage VDD1 is higher than a first preset voltage level and the voltage level of the second external voltage VDD2 is lower than a second preset voltage level. The initialization block 120 disables the initialization signal INI_s when both the voltage levels of the first and second external voltages VDD1 and VDD2 are higher than the preset voltage levels.

In detail, the first external voltage VDD1 and the second external voltage VDD2 are initially applied to the semiconductor apparatus. The first external voltage VDD1 is applied to the semiconductor apparatus earlier than the second external voltage VDD2, and starts to be raised in its voltage level, earlier than the second external voltage VDD2. Also, the first external voltage VDD1 is a voltage which has a target level higher than the voltage level of the second external voltage VDD2. That is, a first target level of the first external voltage VDD1 is higher than a second target level of the second external voltage VDD2.

Accordingly, as shown in FIG. 2, the first external voltage VDD1 is applied to the semiconductor apparatus earlier than the second external voltage VDD2, and is raised in its voltage level earlier than the second external voltage VDD2. After the voltage level of the first external voltage VDD1 reaches the first target voltage level, the second external voltage VDD2 is applied to the semiconductor apparatus, and then, the voltage level of the second external voltage VDD2 reaches the second target voltage level. The initialization block 120 enables the initialization signal INI_s when the voltage level of the first external voltage VDD1 is higher than the preset voltage level, and disables the initialization signal INI_s when the voltage level of the second external voltage VDD2 is higher than the preset voltage level. That is to say, when the initialization signal INI_s is disabled corresponds to when both the first external voltage VDD1 and the second external voltage VDD2 are higher than the present voltage levels.

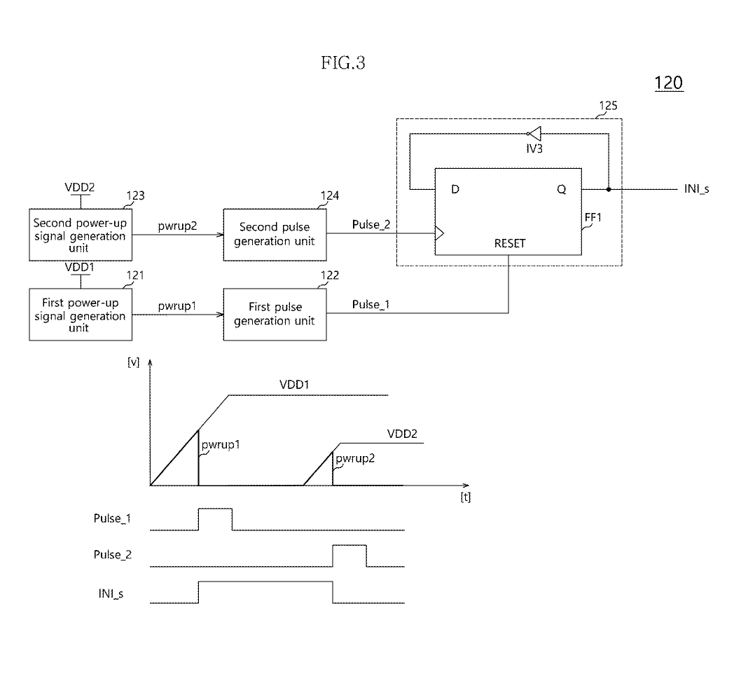

As shown in FIG. 3, the initialization block 120 in accordance with the embodiment may include a first power-up signal generation unit 121, a first pulse generation unit 122, a second power-up signal generation unit 123, a second pulse generation unit 124, and an initialization signal output unit 125.

The first power-up signal generation unit 121 enables a first power-up signal pwrup1 when the voltage level of the first external voltage VDD1 reaches a first preset voltage level. For example, the first power-up signal generation unit 121 enables the first power-up signal pwrup1 to a low level when the voltage level of the first external voltage VDD1 reaches the first preset voltage level after the is first external voltage VDD1 is initially applied to the semiconductor apparatus.

The first pulse generation unit 122 generates a first pulse Pulse_1 in response to the first power-up signal pwrup1. For example, the first pulse generation unit 122 generates the first pulse Pulse_1 which is enabled for a predetermined time, when the first power-up signal pwrup1 is enabled to the low level.

The second power-up signal generation unit 123 enables a second power-up signal pwrup2 when the voltage level of the second external voltage VDD2 reaches a second preset voltage level. For example, the second power-up signal generation unit 123 enables the second power-up signal pwrup2 to a low level when the voltage level of the second external voltage VDD2 reaches the second preset voltage level after the second external voltage VDD2 is initially applied to the semiconductor apparatus.

The second pulse generation unit 124 generates a second pulse Pulse_2 in response to the second power-up signal pwrup2. For example, the second pulse generation unit 124 generates the second pulse Pulse_2 which is enabled for a predetermined time, when the second power-up signal pwrup2 is enabled to the low level.

The initialization signal output unit 125 generates the initialization signal INI_s in response to the first and second pulses Pulse_1 and Pulse_2. For example, the initialization signal output unit 125 enables the initialization signal INI_s to a high level when the first pulse Pulse_1 is inputted, and disables the initialization signal INI_s to a low level when the second pulse Pulse_2 is inputted. In other words, the initialization signal output unit 125 generates the initialization signal INI_s which is enabled from when the first pulse Pulse_1 is inputted to when the second pulse Pulse_2 is inputted.

The initialization signal output unit 125 may include a flip-flop FF1 and an inverter IV3. The flip-flop FF1 is inputted with the second pulse Pulse_2 through a clock input terminal, is inputted with the first pulse Pulse_1 through a reset input terminal, and has a signal input terminal D to which the output terminal of the inverter IV3 is coupled and a signal output terminal Q to which the input terminal of the inverter IV3 is coupled. The inverter IV3 is inputted with the output signal of the flip-flop FF1, and outputs an output signal as the input signal of the flip-flop FF1. The output signal of the flip-flop FF1 is the initialization signal INI_s.

The operation of the initialization block 120 in accordance with the embodiment, configured as mentioned above, will be described below.

As shown in FIG. 3, the first external voltage VDD1 is applied to the semiconductor apparatus earlier than the second external voltage VDD2, and is raised in its voltage level earlier than the second external voltage VDD2. After the voltage level of the first external voltage VDD1 reaches the first target voltage level, the second external voltage VDD2 is applied to the semiconductor apparatus, and then, the voltage level of the second external voltage VDD2 reaches the second target voltage level. The initialization block 120 enables the first power-up signal pwrup1 when the voltage level of the first external voltage VDD1 is higher than the first preset voltage level, generates the first pulse Pulse_1 when the first power-up signal pwrup1 is enabled, and enables the initialization signal INI_s when the first pulse Pulse_1 is generated. The initialization block 120 enables the second power-up signal pwrup2 when the voltage level of the second external voltage VDD2 is higher than the second preset voltage level, generates the second pulse Pulse_2 when the second power-up signal pwrup2 is enabled, and disables the initialization signal INI_s when the second pulse Pulse_2 is generated. Namely, when the initialization signal INI_s is disabled corresponds to when both the first external voltage VDD1 and the second external voltage VDD2 are higher than the present voltage levels.

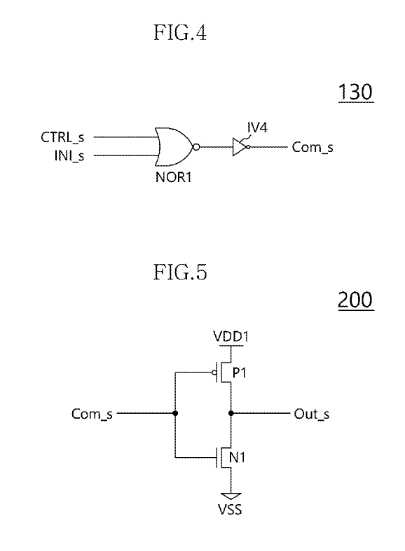

As shown in FIG. 4, the signal combination block 130 may include a NOR gate NOR1 and an inverter IV4. The NOR gate NOR1 is inputted with the control signal CTRL_s and the initialization signal INI_s. The inverter IV4 is inputted with the output signal of the NOR gate NOR1 and outputs the combination signal Com_s.

The signal combination block 130 configured in this way fixes the combination signal Com_s to the specified level, that is, a high level, regardless of the control signal CTRL_s, when the initialization signal INI_s is enabled to the high level. Meanwhile, the signal combination block 130 generates the combination signal Com_s in response to the control signal CTRL_s, when the initialization signal INI_s is disabled to the low level. For example, the signal combination block 130 enables the combination signal Com_s to the high level when the initialization signal INI_s is disabled to the low level and the control signal CTRL_s is enabled to a high level. Moreover, the signal combination block 130 disables the combination signal Com_s to a low level when the initialization signal INI_s is disabled to the low level and the control signal CTRL_s is disabled to a low level.

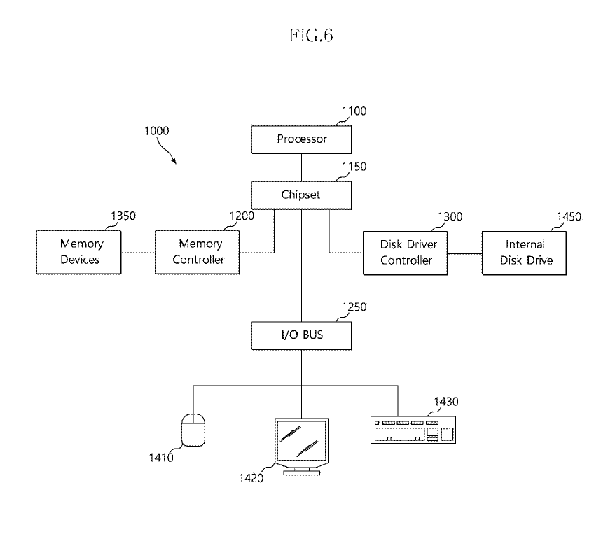

While the internal circuit 200 in accordance with the embodiment is described as a driver which drives the combination signal Com_s and outputs an output signal Out_s as shown in FIG. 5, it is to be noted that the internal circuit 200 is not limited to a driver.

The internal circuit 200 may include first and second transistors P1 and N1. The first transistor P1 has a gate which is inputted with the combination signal Com_s and a source which is applied with the first external voltage VDD1. The second transistor N1 has a gate which is inputted with the combination signal Com_s, a drain to which the drain of the first transistor P1 is coupled, and a source to which a ground terminal VSS is coupled. The output signal Out_s is outputted from a node where the first transistor P1 and the second transistor N1 are coupled.

The operation of the semiconductor apparatus in accordance with the embodiment, configured as mentioned above, will be described below.

The semiconductor apparatus operates by being applied with the first and second external voltages VDD1 and VDD2.

The first and second external voltages VDD1 and VDD2 are applied to the semiconductor apparatus from an exterior. The first external voltage VDD1 is applied earlier than the second external voltage VDD2, and the target level of the first external voltage VDD1 is higher than the target level of the second external voltage VDD2. Since the first external voltage VDD1 is applied to the semiconductor apparatus earlier than the second external voltage VDD2, the first external voltage VDD1 is raised in its voltage level earlier than the second external voltage VDD2.

A period from when the first and second external voltages VDD1 and VDD2 are initially applied to the semiconductor apparatus to when both the first and second external voltages VDD1 and VDD2 are higher than the preset voltage levels will be referred to as the initialization period, and a period after both the first and second external voltages VDD1 and VDD2 are higher than the preset voltage levels will be referred to as the normal period. Minimum voltage levels for the semiconductor apparatus to perform a normal operation are the preset voltage levels of the first and second external voltages VDD1 and VDD2, and the first and second external voltages VDD1 and VDD2 are raised in their voltage levels to the target levels. The semiconductor apparatus performs the initialization operation for the initialization period, and the initialization operation means an operation of initializing the internal circuits of the semiconductor apparatus to be able to normally perform the normal operation.

In the case where the first and second external voltages VDD1 and VDD2 are initially applied to the semiconductor apparatus, the initialization block 120 enables the initialization signal INI_s when the first external voltage VDD1 is higher than the first preset voltage level, and disables the initialization signal INI_s when the second external voltage VDD2 is higher than the second preset voltage level. That is to say, the initialization block 120 generates the initialization signal INI_s which has an enable period from when the first external voltage VDD1 is higher than the first preset voltage level to when the second external voltage VDD2 is higher than the second preset voltage level. In other words, the initialization block 120 generates the initialization signal INI_s which has an enable period of the same size as the initialization period of the semiconductor apparatus.

The signal combination block 130 fixes the combination signal Com_s to the specified level regardless of the control signal CTRL_s, for a period in which the initialization signal INI_s is enabled. For example, the signal combination block 130 fixes the combination signal Com_s to the high level for a period in which the initialization signal INI_s is enabled to the high level.

The internal circuit 200 performs the initialization operation for a period in which the combination signal Com_s is fixed to the specified level. For example, when assuming that the internal circuit 200 is the driver shown in FIG. 5, in the internal circuit 200, the first transistor P1 is turned off and the second transistor N1 is turned on, for the period in which the combination signal Com_s is fixed to the high level. Accordingly, for the period in which the combination signal Com_s is fixed to the high level, the internal circuit 200 outputs the output signal Out_s of only a low level regardless of the control signal CTRL_s. At this time, since the first transistor P1 is turned off and thus the first external voltage VDD1 is not applied to the node where the first and second transistors P1 and N1 are coupled, that is, the node from which the output signal Out_s is outputted, the internal circuit 200 does not consume power. The internal circuit 200 performs the initialization operation of outputting the output signal Out_s of only a specified level, for the period in which the combination signal Com_s is fixed to the specified level.

After the first and second external voltages VDD1 and VDD2 are initially applied to the semiconductor apparatus, if both the first and second external voltages VDD1 and VDD2 are higher than the preset voltage levels, the initialization block 120 disables the initialization signal INI_s.

If the initialization signal INI_s is disabled, the signal combination block 130 outputs the control signal CTRL_s of the control block 110, as the combination signal Com_s. For example, the signal combination block 130 enables the combination signal Com_s to the high level when the initialization signal INI_s is disabled to the low level and the control signal CTRL_s of the control block 110 is enabled to the high level. Moreover, the signal combination block 130 disables the combination signal Com_s to the low level when the initialization signal INI_s is disabled to the low level and the control signal CTRL_s of the control block 110 is disabled to the low level.

As described above, if the initialization signal INI_s is disabled, the combination signal Com_s is generated according to the output of the control block 110, that is, the control signal CTRL_s, and the internal circuit 200 operates in response to the combination signal Com_s generated according to the control signal CTRL_s.

Namely, since the internal circuit 200 operates according to the control of the control block 110 after the initialization signal INI_s is disabled, after the initialization signal INI_s is disabled may be referred to as a normal operation period.

As a consequence, the semiconductor apparatus in accordance with the embodiment performs the initialization operation from when a plurality of external voltages, that is, the first and second external voltages VDD1 and VDD2 are initially applied to the semiconductor apparatus to when both the first and second external voltages VDD1 and VDD2 are higher than the preset voltage levels. In particular, in the case where the internal circuit 200 is a driver, power is not consumed while the initialization operation is performed. In addition, the semiconductor apparatus in accordance with the embodiment may normally perform the normal operation after both the first and second external voltages VDD1 and VDD2 are higher than the preset voltage levels.

While the semiconductor apparatus in accordance with the embodiment discloses a technology of using 2 external voltages, it is to be noted that the semiconductor apparatus in accordance with the embodiment may be configured to perform an initialization operation from when an external voltage (for example, a first external voltage) initially applied to the semiconductor apparatus earliest among a plurality of external voltages is higher than a preset voltage level to until an external voltage (for example, a second external voltage) applied latest among the plurality of external voltages is higher than a preset voltage level.

The semiconductor apparatus discussed above (see FIGS. 1-5) are particularly useful in the design of memory devices, processors, and computer systems. For example, referring to FIG. 6, a block diagram of a system employing a semiconductor apparatus in accordance with the various embodiments are illustrated and generally designated by a reference numeral 1000. The system 1000 may include one or more processors (i.e. processor) or, for example, but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented. In an embodiment, the processor 1100 (i.e., CPU) may include at least one semiconductor apparatus as discussed above with the reference to FIGS. 1-5.

A chipset 1150 may be operably coupled to the processor (i.e., CPU) 1100. The chipset 1150 is a communication pathway for signals between the processor (i.e., CPU) 1100 and other components of the system 1000. In an embodiment, the chipset 1150 may include at least one semiconductor apparatus as discussed above with the reference to FIGS. 1-5. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor apparatus as discussed above with the reference to FIGS. 1-5. In alternate embodiments, the memory controller 1200 may be integrated into the chipset 1150. The memory controller 1200 may be operably coupled to one or more memory devices 1350. In an embodiment, the memory devices 1350 may include the one semiconductor apparatus as discussed above with relation to FIGS. 1-5. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 6 is merely one example of a system 1000 employing a semiconductor apparatus as discussed above with relation to FIGS. 1-5. In alternate embodiments, such as, for example but not limited to, cellular phones or digital cameras, the components may differ from the embodiments illustrated in FIG. 6.

While various embodiments have been described above, it will be understood to those skilled in the art that the embodiments described are examples only. Accordingly, the semiconductor apparatus described herein should not be limited based on the described embodiments.

What is claimed is:

1. A semiconductor apparatus suitable for operating by being applied with a plurality of external voltages from an exterior, comprising:
an initialization block configured to enable an initialization signal until all of the plurality of external voltages are higher than preset voltage levels after the plurality of external voltages are initially applied to the semiconductor apparatus; and
an internal circuit configured to perform an initialization operation in response to the initialization signal.

2. The semiconductor apparatus according to claim 1, wherein the initialization block enables the initialization signal when an external voltage applied earliest among the plurality of external voltages is higher than a preset voltage level, and disables the initialization signal when a signal applied latest among the plurality of external voltages is higher than a preset voltage level.

3. The semiconductor apparatus according to claim 1, further comprising:
a control block configured to generate a control signal for controlling the internal circuit; and
a signal combination block configured to generate a combination signal in response to the control signal and the initialization signal.

4. The semiconductor apparatus according to claim 3, wherein the signal combination block fixes the combination signal to a specified level regardless of the control signal for a period in which the initialization signal is enabled, and generates the combination signal in response to the control signal for a period in which the initialization signal is disabled.

5. The semiconductor apparatus according to claim 4, wherein the internal circuit operates by being inputted with the combination signal.

6. A semiconductor apparatus comprising:
an internal circuit; and
an internal control circuit configured to control the internal circuit for an initialization period from a time when one voltage of a first external voltage and a second external voltage is initially applied to the semiconductor apparatus to a time when both the first and second external voltages reach preset voltage levels, and for a normal period after the initialization period.

7. The semiconductor apparatus according to claim 6, wherein the internal control circuit comprises:
a control block configured to generate a control signal for controlling the internal circuit for the normal period;
an initialization block configured to enable an initialization signal for the initialization period; and
a signal combination block configured to generate a combination signal which is fixed to a specified level, for a period in which the initialization signal is enabled, and generate the combination signal in response to the control signal when the initialization signal is disabled.

8. The semiconductor apparatus according to claim 7,
wherein the internal circuit operates in response to the combination signal, by being applied with the first external voltage as a source voltage,
wherein the control block is applied with the second external voltage as a source voltage,
wherein the initialization block is applied with the first external voltage as a source voltage, and
wherein the signal combination block is applied with the first external voltage as a source voltage.

9. A semiconductor apparatus comprising:
an initialization block configured to generate an initialization signal in response to a first power-up signal and a second power-up signal;
a signal combination block configured to generate a combination signal in response to the initialization signal and a control signal;
a control block configured to generate the control signal; and
an internal circuit configured to operate in response to the combination signal.

10. The semiconductor apparatus according to claim 9,
wherein the first power-up signal is enabled in the case where a first external voltage is higher than a first preset voltage level after being initially applied to the semiconductor apparatus,
wherein the second power-up signal is enabled in the case where a second external voltage is higher than a second preset voltage level after being initially applied to the semiconductor apparatus, and
wherein the first external voltage is applied to the semiconductor apparatus earlier than the second external voltage.

11. The semiconductor apparatus according to claim 10, wherein the initialization block enables the initialization signal from after the first power-up signal is enabled to until the second power-up signal is enabled.

12. The semiconductor apparatus according to claim 11, wherein the initialization block comprises:
a first pulse generation unit configured to generate a first pulse when the first power-up signal is enabled;
a second pulse generation unit configured to generate a second pulse when the second power-up signal is enabled; and
an initialization signal output unit configured to enable the initialization signal when the first pulse is inputted, and disable the initialization signal when the second pulse is inputted.

13. The semiconductor apparatus according to claim 9, wherein the signal combination block fixes the combination signal to a specified level regardless of the control signal for a period in which the initialization signal is enabled, and outputs the control signal as the combination signal when the initialization signal is disabled.

14. The semiconductor apparatus according to claim 1, wherein a target level of a first external voltage is higher than a target level of a second external voltage.

15. The semiconductor apparatus according to claim 14, wherein the initialization block disables the initialization signal when the first and second external voltages reach the preset voltage levels,
wherein the initialization block enables the initialization signal when a voltage level of a first external voltage is higher than a first preset voltage level and a voltage level of a second external voltage is lower than a second preset voltage level,
wherein the voltage level of the first external voltage is raised earlier than the voltage level of the second external voltage,

16. The semiconductor apparatus according to claim 1, wherein the initialization block enables a first power-up signal when a voltage level of a first external voltage reaches a first preset voltage level,
wherein the initialization block enables a second power-up signal when a voltage level of a second external voltage reaches a second preset voltage level.

17. The semiconductor apparatus according to claim 16, wherein the initialization block generates a first pulse which is enabled for a predetermined time in response to the first power-up signal,
wherein the initialization block generates a second pulse which is enabled for another predetermined time in response to the second power-up signal.

18. The semiconductor apparatus according to claim 17, wherein the initialization signal is enabled from when the first pulse is inputted to when the second pulse is inputted,
wherein the initialization signal is disabled when a first external voltage and a second external voltage are higher than the preset voltage levels.

19. The semiconductor apparatus according to claim 1, wherein a voltage level of a first external voltage reaches a first target voltage level before a voltage level of a second external voltage reaches a second target voltage level.
